(19) United States
(12) Patent Application Publication
(10) Pub. No.: US 2017/0055696 A1
(43) Pub. Date: Mar. 2, 2017

(54) WRIST PAD AND METHODS OF USE THEREOF

(71) Applicant: Justin D. Cotton, Atlanta, GA (US)

(72) Inventor: Justin D. Cotton, Atlanta, GA (US)

(21) Appl. No.: 14/839,811

(22) Filed: Aug. 28, 2015

(51) Int. Cl. A47B 21/03; H05K 5/00; H05K 5/02; A44C 5/00; A45F 5/00

(52) U.S. Cl. CPC A47B 21/0371; A44C 5/00; A45F 5/00; H05K 5/0204; H05K 5/0086; A47B 2021/0378; A45F 2005/002; A45F 2005/008

(57) ABSTRACT

A device adapted to provide cushion between an arm and a surface. The device includes an external covering adapted to be in contact with an arm and a surface; an internal cavity inside the external covering; a sealing layer between the external covering and the internal cavity; the sealing layer being adapted to prevent leaking of the cushioning material from the device; and a through-hole.

### TECHNICAL FIELD

The subject disclosure relates to wrist pads used on surfaces with computer pointing devices, commonly known as mice, and more generally to cushioning devices used to provide ergonomic benefits to one or more of a user's arms. More particularly, the present disclosure relates to the use of a wrist pad worn on a computer operator's wrist or forearm, instead of the operator using a wrist rest attached to a mousepad, or no wrist rest apparatus at all, to facilitate the comfortable and ergonomic use of a computer pointing device.

### BACKGROUND

The exponential increases in the availability and popularity of computers in recent decades have likewise increased the availability and popularity of computer accessories, such as computer pointing devices commonly known as mice. Due to the design of pointing devices and the typical arrangement of the operator-computer interface, such as, e.g. with the operator using a computer while seated at a desk, a variety of mousepads and wrist rests have been developed to lessen the fatigue of an operator's wrist and arm during prolonged used of a mouse. However, these devices were initially developed for more stationary use of a computer on a home or office desktop, and the pointing devices were likewise designed to remain on the desktop. As computer technology has evolved to be used wirelessly, such as with laptop and tablet computers, cordless pointing devices, such as, e.g. wirelessly-connected, optical, or BLUETOOTH®-enabled mice, have been developed, which allow computer operators to use computers practically anywhere, rather than merely at desktop stations in home and business offices. In a similar way, it would be advantageous to make the ergonomic benefits of mousepad wrist rests available for operators of these more mobile computers and computer pointing devices.

In addition, the wider range of motion provided by laptops, tablets, and wireless pointing devices is still limited by the relatively small surface of traditional mousepads, to which the currently available wrist rests are attached. A user that prefers to use cordless mice, while still having the ergonomic benefits of a wrist rest, would still be confined to moving the mouse, which has a very wide range of cordless connectivity near the computer, within the constrained area of the mousepad. Furthermore, a wrist rest attached to a currently available mousepad may also become an obstacle when an operator performs a drag-and-drop or scrolling action, which would require the operator to reposition his hand at the top of the mousepad to complete the action. A wrist rest attached to the operator's arm, rather than resting on a desktop or other surface, would provide much greater freedom of movement to complete drag-and-drop and scrolling actions. In addition, as many pointing devices may operate normally on a variety of surfaces, there may be less need for mousepads, which would allow more flexibility regarding the geometry and wearability of a wrist rest, such as, e.g. a wrist rest configured to be worn on a user's wrist or arm. In effect, the desktop or other surface would replace the mousepad, and the wearable wrist rest would replace the stationary wrist rest.

Furthermore, a wearable wrist pad would resolve the lack of ergonomic wrist support for computer operators that prefer to use a stylus, digital pen, touch pad, pointing stick, or isometric joystick with laptops and tablets, as currently available mouse pads are not configured to accommodate the comfortable use of these kinds of computer pointing devices. Overall, the portability of laptop and tablet computers calls for a more portable alternative to customary mousepad wrist rests, which operators may be less likely to carry with them, due to their size and shape relative to the decreasing size of today's and tomorrow's laptop and tablet computers.

Finally, as the use of multiple computers at one desktop station, such as, e.g., using a laptop computer in conjunction with a desktop computer, becomes more common, a computer user would benefit from not having to reposition one mousepad each time she switches between the two computers, or having to purchase and use more than one mousepad, in order to benefit from the wrist rests attached to one or more mousepads. An alternative to available mousepads that would provide the ergonomic benefits of wrist rests, while providing increased range of motion and portability to match that of laptop and tablet computers, and decreased size, would be advantageous.

### SUMMARY

The present disclosure overcomes one or more deficiencies of the prior art. In particular, the device of the subject disclosure achieves increased range of motion and portability of the ergonomic benefits of a wrist pad. A device of the subject disclosure may be adapted to provide cushion between an arm and a surface. The device may include an external covering adapted to be in contact with an arm and a surface; an internal cavity inside the external covering, a sealing layer between the external covering and the internal cavity, the sealing layer being adapted to prevent leaking of the cushioning material from the device, and a through-hole.

The device may be adapted to be worn on a user's wrist or forearm. The may be adapted to be worn by a user while operating a computer pointing device along a surface. The device of claim 1, wherein the external covering is made of a material adapted to move across a surface. The device may further comprise a cushioning material within the internal cavity. The cushioning material may be a plurality of solid objects or a fluid.

The shape of the device may be a torus, a polyhedral torus, a spiral, or a series of interwoven members. The device may further comprise a flat portion of the external covering that is adapted to rest on a surface. The through-hole may be adapted for a hand to fit through it. The device may further comprise a pocket adapted to hold one or more small objects. The pocket may be adapted to hold an electronic apparatus. An external surface of the pocket may be transparent such that a display screen of an electronic apparatus in the pocket cavity is visible through the external surface of the device.

The device may be a torus-shaped device adapted to provide cushion between a user's arm and a surface during the operation of a computer pointing device. The device may comprise an external covering adapted to be in contact with a user's arm and a surface, the external covering being adapted to move across the surface. The device may comprise an internal cavity inside the external covering. The device may comprise a cushioning material within the internal cavity. The device may comprise a sealing layer between the external covering and the internal cavity, and the sealing layer may be adapted to prevent leaking of the cushioning material from the device. The device may comprise a pocket adapted to hold an electronic apparatus, and an external surface of the pocket may be transparent such that a display screen of an electronic apparatus in the pocket is visible through the external surface of the device, and a through-hole adapted for a user's arm to fit through it.

A method for providing cushion between an arm and a surface, may comprise placing a user's hand through the through-hole of a cushioning device, fitting the cushioning device onto a desired part of the user's arm, grasping a computer point device, placing the computer pointing device and user's arm on a surface, operating the computer pointing device on the surface, and removing the cushioning device from the user's arm at the conclusion of use.

### BRIEF DESCRIPTION OF THE DRAWINGS

Various exemplary embodiments of this disclosure will be described in detail, wherein like reference numerals refer to identical or similar components or steps, with reference to the following figures, wherein:

FIG. 1 illustrates a partial perspective view of the wrist pad of the subject disclosure fitted onto an operator's arm, while the operator uses a computer pointing device.

FIGS. 2A and 2B illustrate partial side views of the wrist pad of the subject disclosure fitted onto an operator's arm, while the operator uses a computer pointing device.

FIGS. 3A-3C illustrate top views of an operator using the wrist pad of the subject disclosure with multiple computers on one desktop surface.

FIG. 4 illustrates a perspective view of the wrist pad of the subject disclosure.

FIG. 5 illustrates a cutaway perspective view of the wrist pad of the subject disclosure.

FIGS. 6A-6E illustrate additional exemplary embodiments of the wrist pad of the subject disclosure.

FIG. 7 illustrates a flow chart diagram of a method of using the wrist pad.

### DETAILED DESCRIPTION

Particular embodiments of the present invention will now be described in greater detail with reference to the figures.

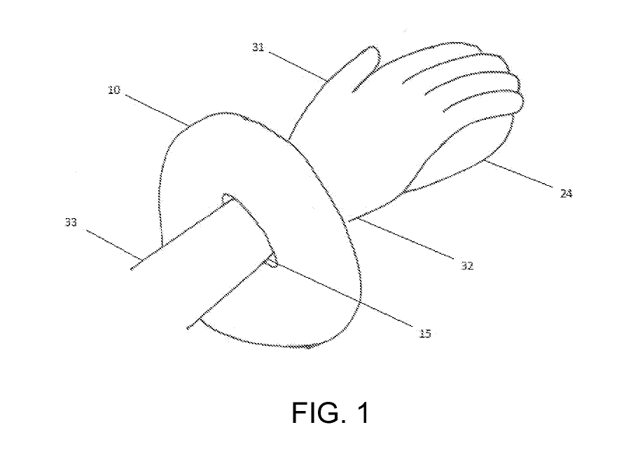

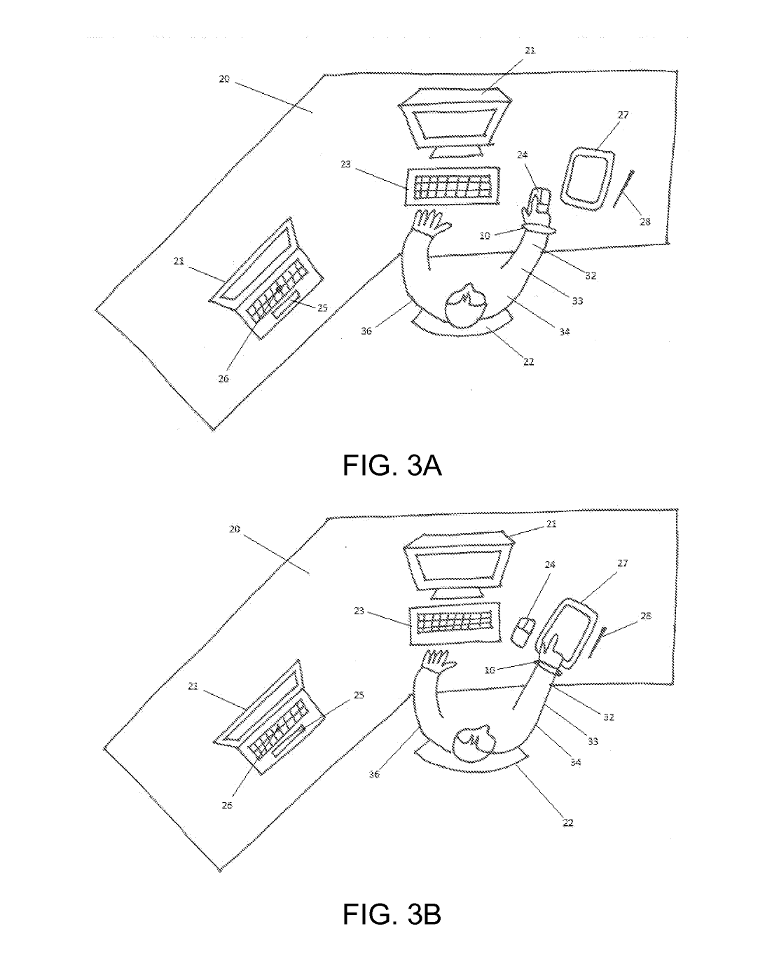

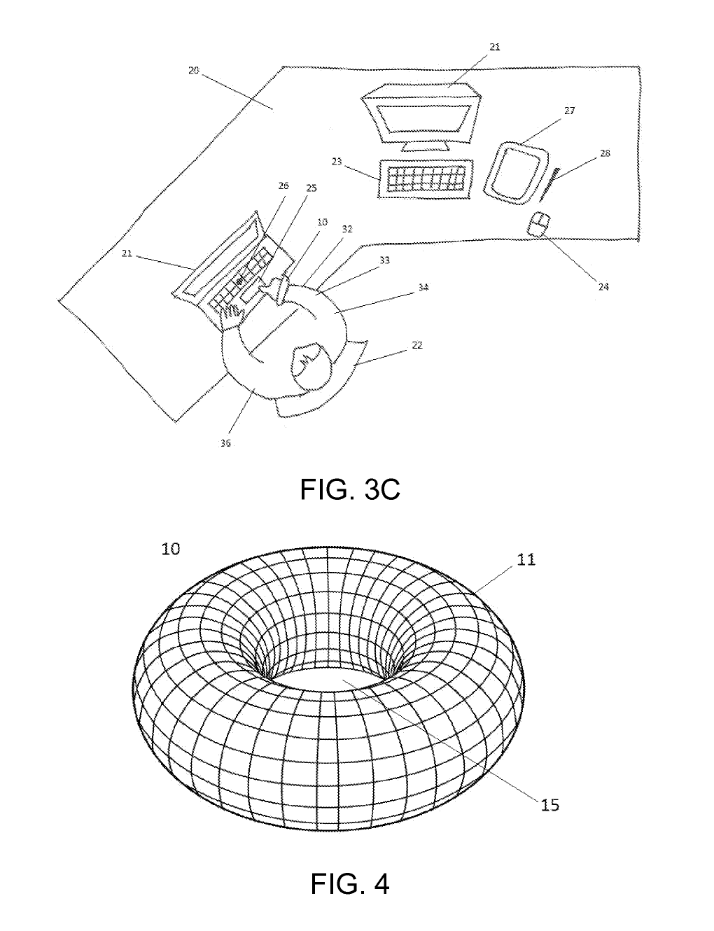

FIG. 1 illustrates the wrist pad 10 of the subject disclosure fitted onto the wrist 32 or forearm 33 of a computer operator, who is using a computer pointing device 24, such as, e.g., a computer mouse, a stylus, pointing stick, touchpad, or a digital pen. The operator may fit the wrist pad 10 on his wrist 32 or forearm 33 by any suitable method, such as, e.g. by placing his hand 31 through the through-hole 15 of the wrist pad 10, or by wearing the wrist pad 10 anywhere on his arm, such as, e.g., as shown in FIG. 3A, on his forearm 33 or upper arm 34, and relocating the wrist pad 10 to a suitable position on his wrist 32 or forearm 33 before using the computer pointer device 24. In one example, the wrist pad 10 may have the shape of a torus, and the through-hole 15 is a circular opening which may be of a suitable size to accommodate a wrist 32, forearm 33, or upper arm 34 to fit through it. The shape of the wrist pad 10 may extend to cover a larger portion of the operator's arm like a sleeve. Various embodiments of the wrist pad 10, as illustrated in FIGS. 6A-6E, may provide various shapes to accommodate different surfaces upon which the wrist pad 10 may be used, as well as branding opportunities, as the wrist pad 10 may be adapted to resemble objects worn by living persons or fictional characters.

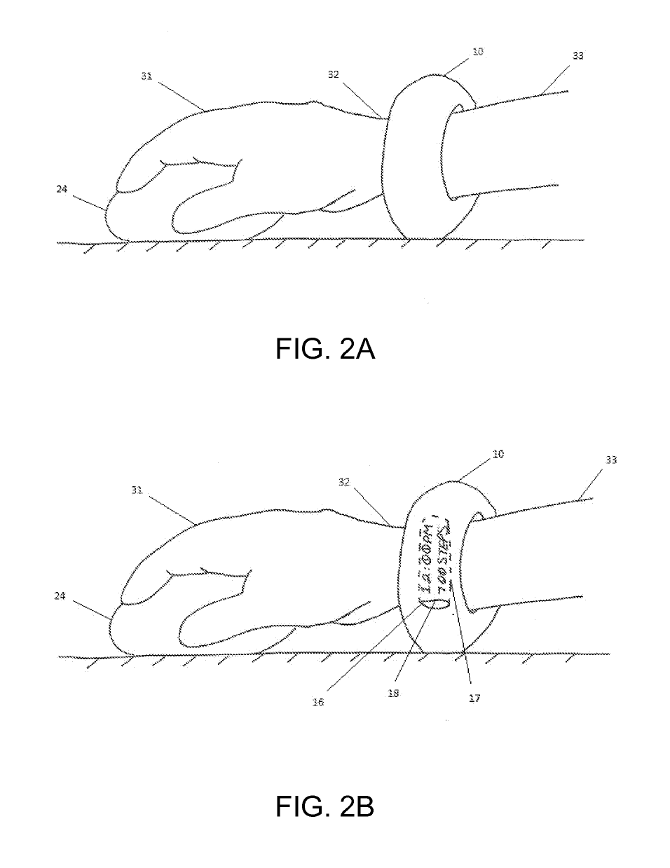

FIG. 2A illustrates a partial side view of an operator using the wrist pad 10 of the subject disclosure with a computer pointing device 24, as described in FIG. 1. FIG. 2B illustrates a partial side view of an operator using another embodiment of the wrist pad 10 of the subject disclosure with a pointing device 24. The wrist pad 10 may have a pocket 16 that may be adapted to hold a permanent or removable electronic apparatus 18, which may be any suitable device as is known in the art, such as, e.g., a clock, a biometric device, a power charging device, or a data storage device. Such a device may be powered by any suitable means as is known in the art, such as, e.g., battery or rechargeable battery, and the information may be transmitted to device by any suitable means as is known in the art, such as, e.g., by BLUETOOTH® or Wi-Fi, which may make its placement in the wrist pad 10 convenient for the user. The electronic apparatus 18 may be inserted into the pocket 16 through a transparent sleeve 17 on the exterior covering 11 of the wrist pad 10. The transparent sleeve 17 may be made of any suitable material to securely hold the electronic apparatus 18 in the sleeve, such as, e.g., the materials described for the external covering 11 in FIG. 4, while allowing a user to read information displayed by the electronic apparatus 18, that may be any suitable information as is known in the art, such as, e.g. time, date, caller ID, calendar information, biometric data, global positioning or GPS data, Internet connection data, data storage information, or information about the proximity of other persons or locations.

FIG. 3 illustrates a top view of an operator 36 using the wrist pad 10 of the subject disclosure with a wireless pointing device on a large desktop surface 20, between multiple computers 21. The wrist pad 10 of the subject disclosure would allow the operator 36 to alternate between using two or more computers 21 by allowing the operator 36 to bring the ergonomic benefits of the wrist pad 10 with him as he reorients himself to face different computers 21, instead of having to move a mousepad on which to rest his wrist, or use more than one mousepad. As illustrated in FIG. 3, the as the operator 36 moves between each computer 21, such as, e.g. by swiveling in an office chair 22, he can more easily switch between working on each computer 21 without spending time to reposition a mousepad, regardless of the kind of computer pointing device he is using at each computer 21, such as, e.g. a mouse, wireless mouse, stylus, digital pen, touch pad, pointing stick, or isometric joystick. Depending on the duration of computer use, the operator 36 may benefit from wearing a wrist pad 10 on both wrists 31.

FIG. 4 illustrates a perspective view of the wrist pad 10 of the subject disclosure. The wrist pad 10 may include external covering 11 and a through-hole 15. The external covering 11 may be made of any suitable material as is known in the art, such as, e.g. a fabric, polymer, plastic, rubber, neoprene, leather, neoprene, or silicone. The external covering 11 may be suitable to display visual content, such as, e.g. advertising and branding content. The diameter of the through-hole 15 may be configured to be any suitable size, such as, e.g. large enough for a computer user's hand, wrist, forearm, or upper arm to fit through. The wrist rest 10 may be elastic, which would allow the wrist rest 10 to fit snugly on different portions of a computer operator's arm for different uses, such as, e.g., the computer operator may wear the wrist rest 10 on her arm while using a computer pointing device, but she may relocate the wrist rest 10 to her forearm or upper arm while performing other tasks, or for decorative purposes.

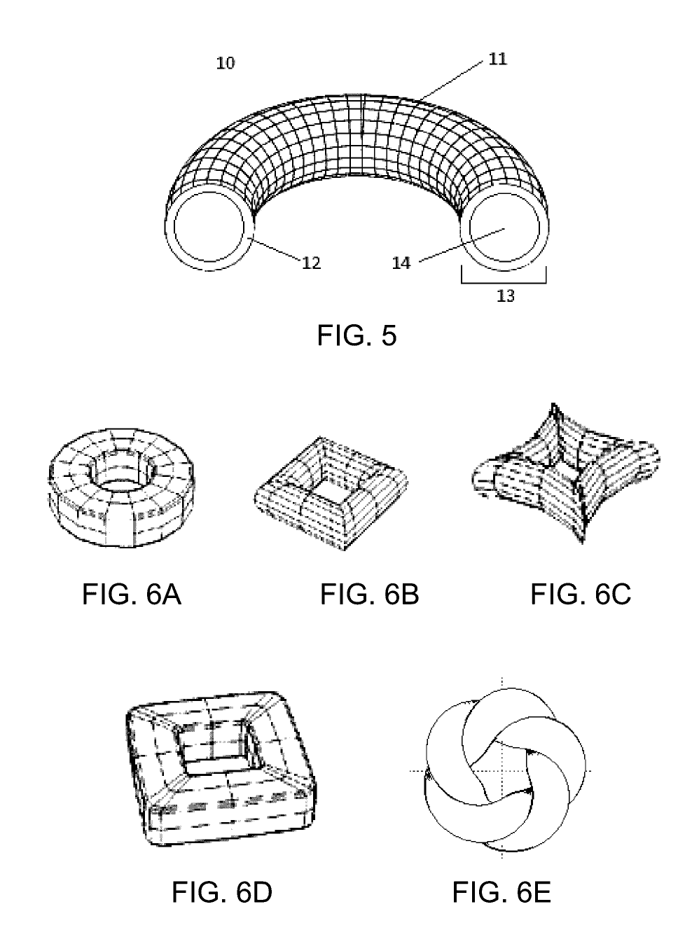

FIG. 5 illustrates a cutaway side view of the wrist pad 10 of the subject disclosure. The wrist pad 10 may have a cross-section of any suitable shape known in the art, such as, e.g. circular, elliptical, polyhedral, or a plurality of cross-sections associated with a twisted torus. The wrist pad 10 may have an internal cavity 13 inside the external covering 11, and there may be a cushioning material 14 inside the internal cavity 13. The cushioning material 14 may be any suitable material as is known in the art, such as, e.g., a gel, a gas, air, a powder, a foam, sand, a plurality of beads, a plurality of ball bearings, or a plurality of pellets. There may be a sealing layer 12 situated between the external layer 11 and the cushioning material 14 that may be adapted to prevent the leaking of cushioning material 14 outside of the wrist pad 10. The sealing layer 12 may be any suitable material as is known in the art, such as, e.g., a fabric, polymer, plastic, rubber, neoprene, leather, neoprene, or silicone.

FIG. 6A illustrates a second exemplary embodiment of the wrist pad 10 of the subject disclosure in the shape of a flat-edged ring, which may have at least one flat surface that may be suitable to rest on a flat surface, such as, e.g. a desktop surface. The corners of the ring may be tapered to an edge, rather than smooth as in the torus of FIG. 4. The shape of the wrist pad 10 may extend to cover a larger portion of the operator's arm like a sleeve.

FIG. 6B illustrates a third exemplary embodiment of the wrist pad 10 of the subject disclosure in the shape of a square or trapezoid, which may have at least one flat surface that may be suitable to rest on a flat surface, such as, e.g., a desktop surface. The corners of the square may be tapered to an edge. The shape of the wrist pad 10 may extend to cover a larger portion of the operator's arm like a sleeve.

FIG. 6C illustrates a fourth exemplary embodiment of the wrist pad 10 of the subject disclosure in the shape of a square or trapezoid, which may have at least one curved surface that may be suitable to rest on a rounded surface, such as, e.g., an operator's leg or the arm of a chair. The corners of the square may be tapered to an edge. The shape of the wrist pad 10 may extend to cover a larger portion of the operator's arm like a sleeve.

FIG. 6D illustrates a fifth exemplary embodiment of the wrist pad 10 of the subject disclosure in the shape of a square or trapezoid, which may have at least one flat surface that may be suitable to rest on a flat surface, such as, e.g., a desktop surface. The corners of the square may be rounded. The shape of the wrist pad 10 may extend to cover a larger portion of the operator's arm like a sleeve.

FIG. 6E illustrates a sixth exemplary embodiment of the wrist pad 10 of the subject disclosure in shape of a twisted torus. The twisted torus shape may be composed of any suitable material as is known in the art, such as, e.g., woven materials, polymers, or any of the materials discussed in the description of FIG. 4. The shape of the wrist pad 10 may extend to cover a larger portion of the operator's arm like a sleeve.

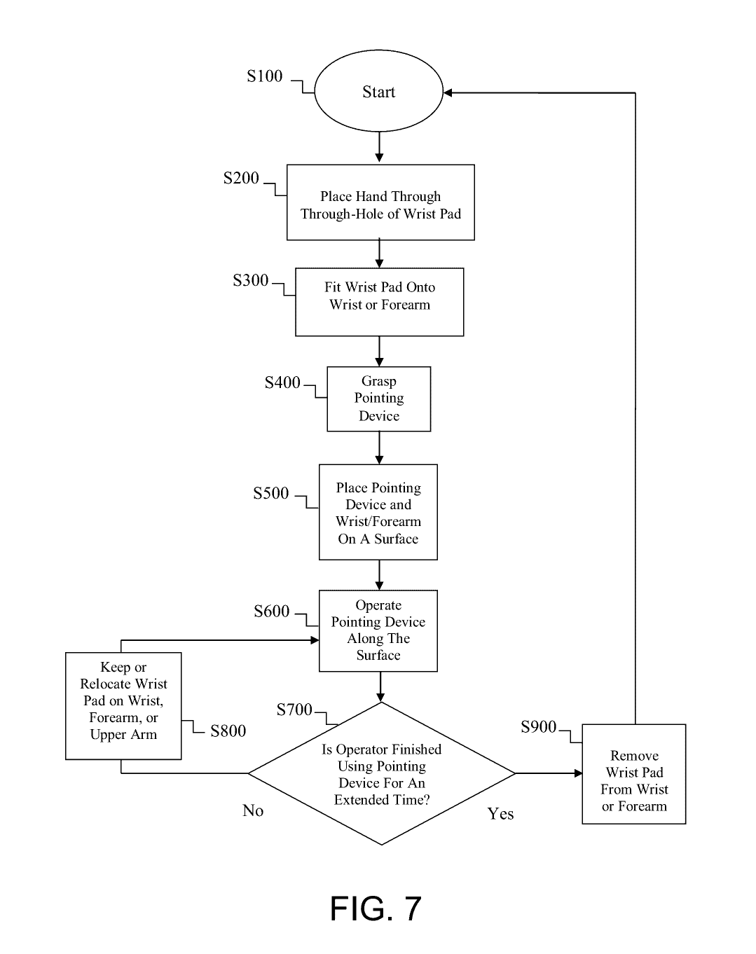

FIG. 7 illustrates a flow chart diagram of a method of using the wrist pad. In step S100, the method starts. In step S200, an operator places her hand 31 through the though-hole 15 of the wrist pad 10. In step S300, the operator fits the wrist pad 10 onto her wrist 32 or forearm 33. In step S400, the operator grasps a pointing device 24. In step S500, the operator places the pointing device 24 and wrist 32 or forearm 33 on a surface. In step S600, the operator uses the pointing device 24 along the surface, with the wrist pad 10 providing ergonomic support to the operator's wrist 32 or forearm 33. In step S700, the operator decides whether she is finished using the wrist pad 10 for an extended period of time. If no, the method proceeds to step S800. If yes, the method proceeds to step S900. In step S800, the operator keeps or relocates the wrist pad 10 on her wrist 32, forearm 33, or upper arm 34 until she uses the pointing device again. The method proceeds to step S600. In step S900, the operator removes the wrist pad 10 from her wrist 32 or forearm 33, and the method ends until the next time the operator needs to use the wrist pad 10.

The wrist pad 10 of the subject disclosure may provide advantages over the mousepads and wrist rests available in the art. The wrist pad 10 of the subject disclosure would allow a computer operator to freely operate a pointing device, such as, e.g., a mouse, or rest his wrist on a surface between intervals of operating a pointing device, such as, e.g. a digital pen, anywhere on a desktop or other surface, without having to continuously return his hard to the mousepad surface. By having the benefits of a customary wrist rest attached to his wrist, a computer operator would have the ergonomic benefits of a wrist rest over a much wider range of motion across a much larger surface area, as computer pointer devices may operate on surfaces without the need for the flat portion of a mouse pad.

The illustrations and examples provided herein are for explanatory purposes and are not intended to limit the scope of the appended claims. It will be recognized by those skilled in the art that changes or modifications may be made to the above described embodiment without departing from the broad inventive concepts of the subject disclosure. It is understood therefore that the subject disclosure is not limited to the particular embodiment which is described, but is intended to cover all modifications and changes within the scope and spirit of the subject disclosure.

1. A device adapted to provide cushion between an arm and a surface, comprising:
an external covering adapted to be in contact with an arm and a surface;
an internal cavity inside the external covering,
a sealing layer between the external covering and the internal cavity, the sealing layer being adapted to prevent leaking of a cushioning material from the device, and
a through-hole.

2. The device of claim 1, wherein the device is adapted to be worn on a user's wrist.

3. The device of claim 1, wherein the device is adapted to be worn on a user's forearm.

4. The device of claim 1, wherein the device is adapted to be worn by a user while operating a computer pointing device along a surface.

5. The device of claim 1, wherein the external covering is made of a material adapted to move across a surface.

6. The device of claim 1, further comprising a cushioning material within the internal cavity.

7. The device of claim 6, wherein the cushioning material is a plurality of solid objects.

8. The device of claim 6, wherein the cushioning material is a fluid.

9. The device of claim 1, wherein the shape of the device is a torus.

10. The device of claim 1, wherein the shape of the device is a polyhedral torus.

11. The device of claim 1, wherein the shape of the device is a spiral.

12. The device of claim 1, wherein the device is a series of interwoven members.

13. The device of claim 1, further comprising a flat portion of the external covering that is adapted to rest on a surface.

14. The device of claim 1, wherein the through-hole is adapted for an arm to fit through it.

15. The device of claim 1, further comprising a pocket adapted to hold one or more small objects.

16. The device of claim 15, wherein the pocket is adapted to hold an electronic apparatus.

17. The device of claim 16, wherein an external surface of the pocket is transparent such that a display screen of an electronic apparatus in the pocket is visible through the external surface of the device.

18. A torus-shaped device adapted to provide cushion between a user's arm and a surface during the operation of a computer pointing device, comprising:
an external covering adapted to be in contact with a user's arm and a surface, the external covering being adapted to move across the surface;
an internal cavity inside the external covering;
a cushioning material within the internal cavity;
a sealing layer between the external covering and the internal cavity, the sealing layer being adapted to prevent leaking of the cushioning material from the device;
a pocket adapted to hold an electronic apparatus, wherein an external surface of the pocket is transparent, such that a display screen of an electronic apparatus in the pocket is visible through the external surface of the device, and
a through-hole adapted for a user's arm to fit through it.

19. A method for providing cushion between an arm and a surface, comprising:
placing a user's hand through the through-hole of a cushioning device,
fitting the cushioning device onto a desired part of the user's arm,
grasping a computer point device,
placing the computer pointing device and user's arm on a surface,
operating the computer pointing device on the surface, and
removing the cushioning device from the user's arm at the conclusion of use.
